(19) United States
(12) Patent Application Publication
(10) Pub. No.: US 2025/0185258 A1
(43) Pub. Date: Jun. 5, 2025

(54) PHASE CHANGE MEMORY WITH PARTIAL SIDEWALL SPACER CONTACT

(71) Applicant: INTERNATIONAL BUSINESS MACHINES CORPORATION, Armonk, NY (US)

(72) Inventors: Timothy Mathew Philip, Albany, NY (US); Ghazi Sarwat Syed, Kilchberg (CH); Benedikt Kersting, Lüdinghausen (DE); Kevin W. Brew, Niskayuna, NY (US); JIN PING HAN, Yorktown Heights, NY (US); Ching-Tzu Chen, Ossining, NY (US); Vara Sudananda Prasad Jonnalagadda, Wallisellen (CH); Abu Sebastian, Adliswil (CH)

(21) Appl. No.: 18/524,693

(22) Filed: Nov. 30, 2023

(51) Int. Cl. H10B 63/10; H10B 63/00; H10N 70/00

(52) U.S. Cl. CPC H10B 63/10; H10B 63/84; H10N 70/841

(57) ABSTRACT

A phase change memory device is provided that includes a stacked structure of a first electrode with a first cross-sectional area, a phase change material that is present on the first electrode, a dielectric material layer that is present on the phase change material layer and a second electrode with a second cross-sectional area that is present on the dielectric layer, wherein the second cross sectional area is greater than the first cross-sectional area. The phase change material device also includes a conductive sidewall spacer that is present on two sidewalls of the stacked structure providing electrical communication between the second electrode and the phase change material. The first electrode is electrically separated from the conductive sidewall spacer.

### BACKGROUND

The present invention generally relates to memory structures, and more particularly to phase change memory.

Phase-change memory (PCM) is a non-volatile solid-state memory technology that exploits the reversible, thermally-assisted switching of phase-change materials, in particular chalcogenide compounds such as GST (Germanium-Antimony-Tellurium), between states with different electrical resistance. The fundamental storage unit (the “cell”) can be programmed into a number of different states, or levels, which exhibit different resistance characteristics. The s programmable cell-states can be used to represent different data values, permitting storage of information.

The pancake cell has emerged as a highly energy efficient phase change memory device that can lower energy consumption for programming. The pancake cell has three main components: heater electrode, a phase change layer, and an outer electrode. The heater electrode may have a small area heater electrode to concentrate current density. The phase change memory (PCM) layer may be a thin active phase change layer that minimizes the switching volume. The outer electrode contacts the active phase change material at a remote location such that current must flow in-plane through the phase change layer.

### SUMMARY

In one embodiment, a phase change memory device is provided that includes a stacked structure of a first electrode with a first cross-sectional area, a phase change material layer that is present on the first electrode, a dielectric material layer that is present on the phase change material layer and a second electrode with a second cross-sectional area that is present on the dielectric layer, wherein the second cross sectional area is greater than the first cross-sectional area. The phase change material device also includes a conductive sidewall spacer that is present on two sidewalls of the stacked structure providing electrical communication between the second electrode and the phase change material. The first electrode is electrically separated from the conductive sidewall spacer.

In one embodiment, a phase change memory device is provided that includes a stacked structure of a first electrode with a first cross-sectional area, a projection liner layer on the first electrode, a phase change material layer that is present on the projection liner layer, a dielectric material layer that is present on the phase change material layer and a second electrode with a second cross-sectional area that is present on the dielectric layer, wherein the second cross sectional area is greater than the first cross-sectional area. The phase change material device also includes a conductive sidewall spacer that is present on two sidewalls of the stacked structure providing electrical communication between the second electrode and the phase change material. The first electrode is electrically separated from the conductive sidewall spacer.

In one embodiment, a phase change memory device is provided that includes a stacked structure of a first electrode with a first cross-sectional area, a phase change material layer that is present on the first electrode, a threshold voltage reduction layer that is present on the phase change material layer, a dielectric material layer that is present on the threshold voltage reduction layer and a second electrode with a second cross-sectional area that is present on the dielectric layer, wherein the second cross sectional area is greater than the first cross-sectional area. The phase change material device also includes a conductive sidewall spacer that is present on two sidewalls of the stacked structure providing electrical communication between the second electrode and the phase change material. The first electrode is electrically separated from the conductive sidewall spacer.

In another aspect, a method of forming a phase change memory device is provided. In one embodiment, the method may include forming a material stack on a first electrode. The material stack includes a phase change material layer that is present on the first electrode, a dielectric layer that is present on the phase change material layer, and a second electrode layer that is present on the phase change material layer. The material stack may be etched along a first direction to form a first cell. A bit line is formed atop the second electrode layer. The bit line and the stack are then etched along a section direction. A conducting material is then deposited conformally to provide a conformal liner around two sidewalls of a cell provided by the etched stack. The conformal liner of the conducting material may then be etched back to provide two conductive sidewall spacers in electrical communication between the second electrode and the sidewall of two sides of the phase change material layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a perspective view that illustrates a phase change memory device that includes a conductive sidewall spacer that provides electrical communication between a top electrode and the phase change material layer without shorting to the wall electrode that provides the heater, in accordance with one embodiment of the present disclosure.

FIG. 2 is a perspective view that illustrates a phase change memory device, in which the conductive sidewall spacers 30 does not extend along the entirety of the bit line 25, in accordance with one embodiment of the present disclosure.

FIG. 3 is a perspective view that illustrates a phase change memory device including conductive sidewall spacers that extend along an entirety of the bit line, and a resistive projection liner, in accordance with one embodiment of the present disclosure.

FIG. 4 is a perspective view that illustrates a phase change memory device including conductive sidewall spacers that do not extend along an entirety of the bit line, and a resistive projection liner, in accordance with one embodiment of the present disclosure.

FIG. 5 is a perspective view that illustrates a phase change memory device including conductive sidewall spacers that extend along an entirety of the bit line, and a threshold voltage reduction liner, in accordance with one embodiment of the present disclosure.

FIG. 6 is a perspective view that illustrates a phase change memory device including conductive sidewall spacers that do not extend along an entirety of the bit line and a threshold voltage reduction liner, in accordance with one embodiment of the present disclosure.

FIG. 7 is a perspective view that illustrates a phase change memory device including conductive sidewall spacers that extend along an entirety of the bit line, a resistive projection liner and a threshold voltage reduction liner, in accordance with one embodiment of the present disclosure.

FIG. 8 is a perspective view that illustrates a phase change memory device including conductive sidewall spacers that do not extend along an entirety of the bit line, a resistive projection liner and a threshold voltage reduction liner, in accordance with one embodiment of the present disclosure.

FIG. 9 is a side cross-sectional view along section line AA of the geometry depicted in FIG. 1 that illustrates one embodiment of an initial structure used in a method for forming the structure depicted in FIG. 1.

FIG. 10 is a side cross-sectional view along section line BB of the geometry depicted in FIG. 1 for the initial structure depicted in FIG. 9.

FIG. 11 is a side cross-sectional view along section line AA of the geometry depicted in FIG. 1 that illustrates one embodiment of forming the phase change material layer, dielectric layer and top electrode on the structure depicted in FIG. 9.

FIG. 12 is a side cross-sectional view along section line BB of the geometry depicted in FIG. 1 for the process step depicted in FIG. 11.

FIG. 13 is a side cross-sectional view along section line AA of the geometry depicted in FIG. 1 for one embodiment of etching a stack from the structure depicted in FIG. 11.

FIG. 14 is a side cross-sectional view along section line BB of the geometry depicted in FIG. 1 for the process step depicted in FIG. 13.

FIG. 15 is a side cross-sectional view along section line AA of the geometry depicted in FIG. 1 for one embodiment of filling the openings formed by the etch step described in FIGS. 13 and 14 with a dielectric material.

FIG. 16 is a side cross-sectional view along section line BB of the geometry depicted in FIG. 1 for the process step depicted in FIG. 15.

FIG. 17 is a side cross-sectional view along section line AA of the geometry depicted in FIG. 1 for one embodiment of forming a bit line metal.

FIG. 18 is a side cross-sectional view along section line BB of the geometry depicted in FIG. 1 for the process step depicted in FIG. 17.

FIG. 19 is a side cross-sectional view along section line AA of the geometry depicted in FIG. 1 for one embodiment of etching the bit line metal to provide the geometry of the bit line.

FIG. 20 is a side cross-sectional view along section line BB of the geometry depicted in FIG. 1 for the process step depicted in FIG. 19.

FIG. 21 is a side cross-sectional view along section line AA of the geometry depicted in FIG. 1 for one embodiment of forming a conformal liner of material for the conductive sidewall spacer.

FIG. 22 is a side cross-sectional view along section line BB of the geometry depicted in FIG. 1 for the process step depicted in FIG. 19.

FIG. 23 is a side cross-sectional view along section line AA of the geometry depicted in FIG. 1 for one embodiment of applying an etch back process to the conformal liner of to provide the geometry for the conductive sidewall spacer.

FIG. 24 is a side cross-sectional view along section line BB of the geometry depicted in FIG. 1 for the process step depicted in FIG. 23.

FIG. 25 is a side cross-sectional view along section line AA of the geometry depicted in FIG. 2 for one embodiment of etching a stack including a phase change material layer, a dielectric layer and a top electrode to confine the structure in the AA cross-section.

FIG. 26 is a side cross-sectional view along section line BB of the geometry depicted in FIG. 2 for the process step depicted in FIG. 25.

FIG. 27 is a side cross-sectional view along section line AA of the geometry depicted in FIG. 2 for one embodiment of forming a conductive sidewall spacer.

FIG. 28 is a side cross-sectional view along section line BB of the geometry depicted in FIG. 2 for the process step depicted in FIG. 27.

FIG. 29 is a side cross-sectional view along section line AA of the geometry depicted in FIG. 2 for one embodiment of forming a bit line metal.

FIG. 30 is a side cross-sectional view along section line BB of the geometry depicted in FIG. 2 for the process step depicted in FIG. 29.

FIG. 31 is a side cross-sectional view along section line AA of the geometry depicted in FIG. 2 for one embodiment of applying an etch process to etch the bit line metal to provide a geometry for the bit line.

FIG. 32 is a side cross-sectional view along section line BB of the geometry depicted in FIG. 2 for the process step depicted in FIG. 31.

FIG. 33 is a side cross-sectional view along section line AA of the geometry depicted in FIG. 2 illustrating removing an etch mask and depositing a fill dielectric to the structure depicted in FIG. 31.

FIG. 34 is a side cross-sectional view along section line BB of the geometry depicted in FIG. 2 for the process step depicted in FIG. 33.

### DETAILED DESCRIPTION

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The terms “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

The development of phase change memory faces several challenges. For example, although pancake cell type phase change memory has emerged as a highly energy efficient device that can lower energy consumption for programming, in some instances a disadvantage has been discovered in that a 360 degree wrap around sidewall spacer can short the device. More particularly, a 360 degree wrap around sidewall spacer contact can short out a wall electrode, e.g., the wall electrode of the heater.

In some embodiments, the structures and methods of the present disclosure can overcome the aforementioned difficulties by forming a spacer on two sidewalls of the phase change memory cell that obstruct electrical features from shorting to the wall electrode of the device. For example, along only two sidewalls of the phase change memory cell, e.g., having four sidewalls, a conductive sidewall spacer may run along an entirety of a bit line. The spacer is not present on the sidewalls that run along the edge of the wall heater. In other embodiments, it is not necessary that the conductive sidewall spacer runs along an entirety of the bit line. Additionally, as described herein, the structures and methods of the present disclosure may also be integrated with devices including projection liners, as well as material layers that reduce the threshold voltage (Vth) for effectuating phase changes in phase change memory.

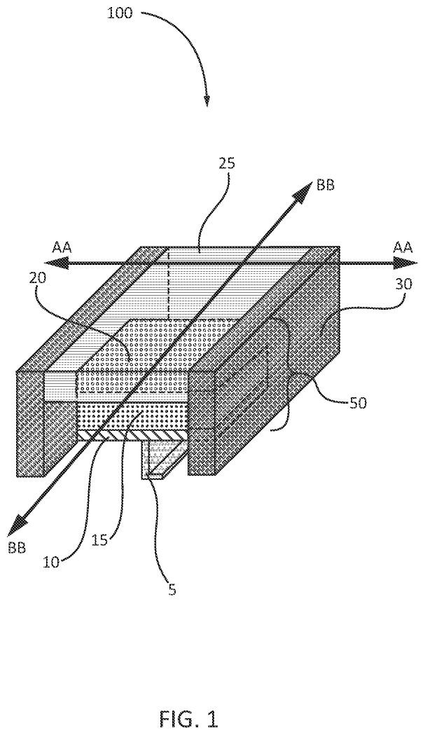

The methods and structures of the present disclosure are now discussed in greater detail with reference to FIGS. 1-34.

FIG. 1 is a perspective view of a phase change memory device 100 including a stacked structure 50 of a first electrode 5 with a first cross-sectional area, a phase change material 10 that is present on the first electrode 5, a dielectric material layer 15 that is present on the phase change material layer 10 and a second electrode 20 with a second cross-sectional area that is present on the dielectric layer 15, wherein the second cross sectional area is greater than the first cross-sectional area. The phase change material device 100 also includes a conductive sidewall spacer 30 that is present on two sidewalls of the stacked structure 50 providing electrical communication between the second electrode 20 and the phase change material 10. The first electrode 5 is electrically separated from the conductive sidewall spacer 30.

The active element of the phase change memory device 100 is the phase change material layer 10. The term “phase change memory (PCM)” refers to a memory technology based on phase change materials, such as chalcogenide materials, that undergo a phase change via a heater (or current) and are read out as “0” or “1” based on their electrical resistivity, which changes in correspondence to whether the phase change material in the cell is in the crystalline or amorphous phase. The chalcogenide materials used in PCM comprise a large number of binary, ternary, and quaternary alloys of a number of metals and metalloids. Phase change memory (PCM) is a non-volatile solid-state memory technology that utilizes phase change materials having different electrical properties in their crystalline and amorphous phases. Specifically, the amorphous phase has a higher resistance than the crystalline phase. The term “amorphous phase” denotes a solid that lacks the long-range order that is characteristic of a crystal. A “crystalline phase” is a type of solid whose fundamental three-dimensional structure consists of a highly regular pattern of atoms or molecules, forming a crystal lattice.

PCM cells are often programmed using heat generated by an electrical current to control the state of phase change materials 10 through the first electrode 5. Among the main key parameter of PCM technology are: RESET current and SET speed. RESET current affects the overall power consumption of the memory array, while SET speed controls the overall speed of the memory array.

Phase change based memory materials, like chalcogenide based materials and similar materials, can be caused to change between an amorphous phase and a crystalline phase by application of electrical current at levels suitable for implementation in integrated circuits. The amorphous phase is characterized by higher electrical resistivity than the crystalline phase, which can be readily read to indicate DATA. These properties are applicable for use as programmable resistive materials to form non-volatile memory circuits, which can be read and written with random access.

The change from the amorphous phase to the crystalline phase is generally a lower current operation. The change from crystalline to amorphous, referred to as RESET herein, is generally a higher current operation, which includes a short high current density pulse to melt or breakdown the crystalline structure, after which the phase change material cools quickly, quenching the phase change process and allowing at least a portion of the phase change material to stabilize in the amorphous phase.

Referring to FIG. 1, the composition of the phase change material layer 10, which provides the crystalline stage phase change material and the amorphous stage phase change material in the active region of the device 100 may be a germanium (Ge), antimony (Sb), and tellurium (Te) (GST) composition. For example, the matrix phase change material of memory device may comprise Ge₂Sb₂Te₅. Other phase change materials may be used, including Ge(x)Sb(2y)Te(x+3y), where x and y are integers (including 0). Other basis phase change materials other than GeSbTe-based materials can also be used, including GaSbTe system, which can be described as Ga (x)Sb(x+2y)Te(3y), and x, y are integers. Alternatively, the basis phase change material can be selected from an Ag(x)In(y)Sb₂Te₃ system, where x, y decimal numbers that can be below 1. In some embodiments, matrix of the phase material may include additional additives to the base of Ge₂Sb₂Te₅. However, many other phase change based memory materials have been contemplated for the matrix of the composite phase change material layer 50, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In one embodiment, the composition of the phase change material layer 10 has an average concentration of Te below 70%, typically below about 60%, and ranged in general from as low as about 23% up to about 58% Te. Concentrations of Ge can be above about 5% and can range from a low of about 8% to about 30% average in the material. In some examples, the germanium (Ge) content is below 50%. The remainder of the principal constituent elements in this composition was Sb. These percentages are atomic percentages that total 100% of the atoms of the constituent elements.

The phase change memory layer 10 that is employed in the present disclosure has a thickness that may be referred to as being “ultra-thin”. This means that the thickness is less than 20 nm. For example, in some embodiments the thickness may be less than 15 nm, e.g., ranging from 1 nm to 15 nm. In other examples, the thickness may range from 5 nm to 15 nm. It is noted that these examples are provided for illustrative purposes only, and are not intended to limit the present disclosure.

Referring to FIG. 1, the phase change memory device 100 further includes a first electrode 5, and a second electrode 20 positioned at opposing faces, i.e., sides, of the phase change material layer 10. The first electrode 5 may be in direct contact with a portion of a face of the phase change material layer 10 on one side of the stack 50. The second electrode 20 is on the opposing side of the phase change material layer 10, in which a dielectric layer 15 is present between the second electrode 20 and the phase change material layer 10. In the embodiment, that is depicted in FIG. 1, the second electrode 20, the dielectric layer 15 and the phase change memory layer 10 all have the same width and depth dimensions, and may be referred to as stacked layers. The first electrode 5 only contacts a portion of the phase change material layer 10. In this manner, the cross-sectional area of the first electrode 5 is less than the cross-sectional area of the second electrode 20.

The first electrode 5 in some instances may be referred to as a heater, or wall electrode. In some embodiments, each of the first and second electrode 20 may be composed of a metallic material may include, but is not limited to, titanium nitride (TiN), tungsten (W), silver (Ag), gold (Au), aluminum (Al) or multilayered stacks thereof. In the embodiment that is depicted in FIG. 1, the first electrode 5 (also referred to as heater/wall contact) is only in direct contact with a portion of a face of the phase change material layer 10. This is the portion of the phase change material layer 10 that initially experiences phase change in response to the application of current by the first electrode 5 (also referred to as heater/wall contact).

Although not depicted in the FIG. 1, the first electrode 5 may be embedded in an insulating material, in which the combination of the insulating material and the first electrode 5 provide a layer in the stack 50. Further, although a single first electrode 5 is described and illustrated, a plurality of first electrodes may be present in this layer of the stack 50. The insulating material may comprise any dielectric material including for example, silicon dioxide, silicon nitride, silicon oxynitride, silsesquioxanes, or C doped oxides (i.e., organosilicates) that include atoms of Si, C and H.

The dielectric layer 15 may be composed of a nitride or oxide type dielectric material. For example, the dielectric layer 15 may be composed of silicon oxide, silicon nitride or silicon oxynitride. The dielectric layer 15 is an electrically insulating structure between the second electrode 20 and the phase change material layer 10 that the dielectric layer 15 is in direct contact with.

Still referring to FIG. 1, the phase change memory device 100 also includes a conductive sidewall spacer 30 that is present on two sidewalls of the stacked structure 50 providing electrical communication between the second electrode 20 and the phase change material 10. The conductive sidewall spacer 30 may be composed of a metal or electrically conductive metal nitride. For example, the conductive sidewall spacer 30 may be composed of titanium (Ti), titanium nitride (TiN), tantalum (Ta), tantalum nitride (TaN), tungsten (W), silver (Ag), gold (Au), aluminum (Al) or multilayered stacks thereof. In the embodiment that is depicted in FIG. 1, the stack 50 composed of the second electrode 20, the dielectric layer 15, the phase change material layer 10 and the first electrode has four sides, e.g., like a quadrilateral, and therefore has four sidewalls, in addition to the top and bottom faces of the stack 50. In some embodiments, the conductive sidewall spacer 30 is present on only two of the four sidewalls, e.g., on a set of opposing sidewalls for the stack. The sidewalls that the conductive sidewall spacers 30 are formed on do not intersect with the first electrode 5 (also referred to as heater/wall electrode).

FIG. 1 illustrates one embodiment, in which the conductive sidewall spacer 30 is present along an entirety of an overlying bit line. The bit line is identified by reference number 25 and is in direct contact with the second electrode 20. In some embodiments, the bit line 25 is between the two conductive sidewall spacers 30. The bit line 25 may be composed of a metal or electrically conductive metal nitride. For example, the bit line 25 may be composed of titanium (Ti), titanium nitride (TiN), tantalum (Ta), tantalum nitride (TaN), tungsten (W), silver (Ag), gold (Au), aluminum (Al) or multilayered stacks thereof.

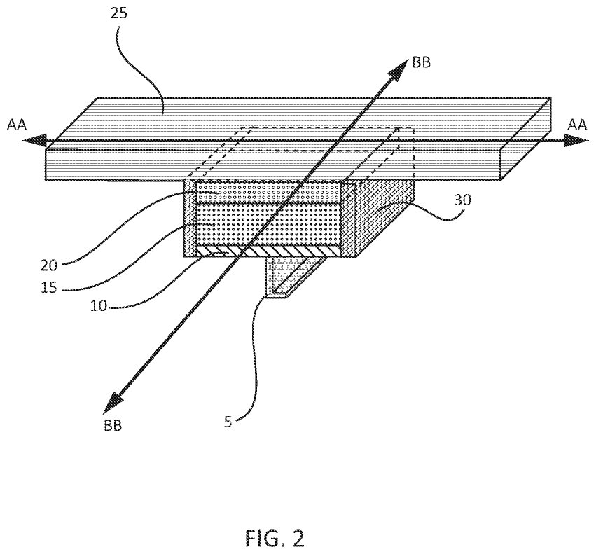

FIG. 2 illustrates another embodiment of the present disclosure. It is not necessary that the conductive sidewall spacers 30 extend along the entirety of the bit line 25, as depicted in FIG. 1. For the structures depicted in FIGS. 1 and 2, the first electrode 5 is electrically separated from the conductive sidewall spacer 30, i.e., they are not in direct contact, and they are not electrically shorted to one another.

FIG. 2 illustrates an embodiment, in which the conductive sidewall spacers 30 do not extend along the entirety of the bit line 25. It is noted that the embodiments depicted in FIGS. 1 and 2 have similar elements. Therefore, structures having the same reference numbers in FIGS. 1 and 2 may be described using the same descriptions for those structures that share reference numbers.

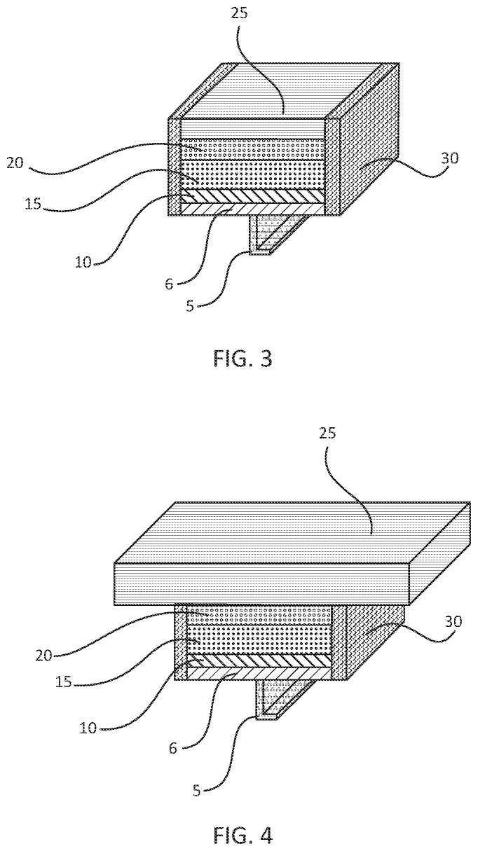

FIGS. 3 and 4 depict another embodiment of the present disclosure in which the stacked structure 50 of the phase change memory device 100 further includes a resistive projection liner 6. The resistive projection liner 6 is a layer that is present between the first electrode 5 and the phase change material layer 10. The resistive projection liner 6 can reduce resistance drift and noise. The resistive projection liner 6 may be comprised of a non-phase change material could decouple the read operation from the write operation and help mitigate the non-ideal attributes such as drift and noise. FIG. 3 illustrates a phase change memory device including conductive sidewall spacers 30 that extend along an entirety of the bit line 25, and a resistive projection liner 6. FIG. 4 illustrates a phase change memory device 100 including conductive sidewall spacers 30 that do not extend along an entirety of the bit line 25, and a resistive projection liner 6.

In some embodiments, the resistive projection liner 6 is a metal nitride, metal oxide, doped semiconductor, small bandgap semiconductor, topological insulator, topological semimetals, a Van der Waal material or a combination thereof. The electrical resistance of the resistive projection liner has greater electrical resistance than the crystalline phase of the crystalline phase change material layer 10 and has less electrical resistance than the resistance through the amorphous phase of the phase change material layer 10.

In some embodiments, when the resistive projection liner 6 is a metal nitride, the metal nitride may be selected from titanium nitride (TiNₓ), tantalum nitride (TaNₓ), tungsten nitride (WNₓ), aluminum nitride (AlNₓ) and combinations thereof. In some embodiments, when the projection material 53 is a doped semiconductor, the doped semiconductor may be selected from doped Si, doped SiGe, doped silicon carbide (SiC), doped germanium (Ge), and combinations thereof.

In some embodiments, the resistive projection liner 6 is a small bandgap semiconductor. Narrow (small)-gap semiconductors are semiconducting materials with a band gap that is comparatively small compared to that of silicon, i.e., smaller than 1.11 eV at room temperature. In some embodiments, when the resistive projection liner 6 is a small bandgap semiconductor, the composition can be selected from tin telluride, titanium telluride, germanium, selenium, InSb, InAs, GaSb, AlSb and combinations thereof.

In some embodiments, the resistive projection liner 6 may be a semimetal. A semimetal is a material with a very small overlap between the bottom of the conduction band and the top of the valence band. In some examples, when the resistive projection liner 6 is a semimetal, it may be selected from bismuth, tin (Sn), mercury, graphite and combinations thereof.

In other examples, the resistive projection liner 6 may be a topological insulator. Topological insulators are quantum matter that features a bulk gap and an odd number of relativistic Dirac fermions on their surfaces. While their bulk is insulating, the surfaces can conduct electric current with a well-defined spin texture. In some examples, the topological insulator for the resistive projection liner 6 may be Bi₂Se₃, BiSb, BiSbTe and combinations thereof.

In further examples, the resistive projection liner 6 may be a topological semiconductor. Topological semiconductors are quantum matter that features a bulk gap and an odd number of relativistic Dirac fermions on their surfaces. While their bulk is insulating, the surfaces can conduct electric current with a well-defined spin texture. In some examples, the topological insulator for the resistive projection liner 6 may be Bi₂Se₃, BiSb, BiSbTe and combinations thereof.

In some examples, the resistive projection liner 6 may be a topological semiconductor. Topological semimetals define a class of gapless electronic phases exhibiting topologically stable crossings of energy bands. Topological semimetals, such as Dirac, Weyl, or line-node semimetals, are gapless states of matter characterized by their nodal band structures and surface states. Some examples of suitable topological semiconductors may include graphene, Weyl semimetals like TaAs and WTe₂, and Dirac semimetals like Na₃Bi or Cd₃As.

In a further example, the projection material comprises a Van der Waal material selected from the group consisting of WTe₂, MoTe₂, TiTe₂, and combinations thereof.

It is noted that the embodiments depicted in FIGS. 1-4 have similar elements. Therefore, structures having the same reference numbers in FIGS. 3 and 4 may be described using the same descriptions for those structures that share reference numbers in FIGS. 1 and 2.

FIG. 3 is a perspective view that illustrates a phase change memory device including conductive sidewall spacers that extend along an entirety of the bit line, and a resistive projection liner, in accordance with one embodiment of the present disclosure.

FIG. 4 is a perspective view that illustrates a phase change memory device including conductive sidewall spacers that do not extend along an entirety of the bit line, and a resistive projection liner, in accordance with one embodiment of the present disclosure.

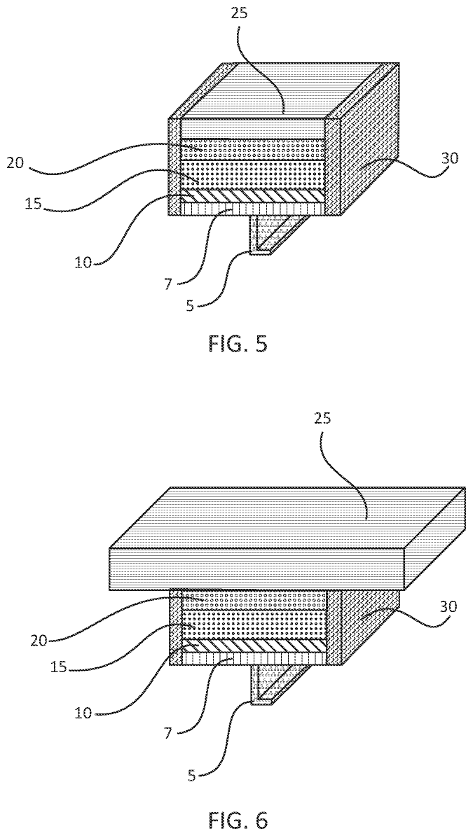

FIGS. 5 and 6 depict yet another embodiment of the present disclosure. In the embodiments depicted in FIGS. 5 and 6, a threshold voltage reduction liner 7 is present between the phase change material layer 10 and the dielectric layer 15.

In some embodiments, the threshold voltage reduction liner 7 is a small bandgap semiconductor. Narrow (small)-gap semiconductors are semiconducting materials with a band gap that is comparatively small compared to that of silicon, i.e., smaller than 1.11 eV at room temperature. In some embodiments, when the resistive projection liner 6 is a small bandgap semiconductor, the composition can be selected from tin telluride, titanium telluride, germanium, selenium, InSb, InAs, GaSb, AlSb and combinations thereof.

FIG. 5 is a perspective view that illustrates a phase change memory device including conductive sidewall spacers that extend along an entirety of the bit line, and a threshold voltage reduction liner, in accordance with one embodiment of the present disclosure.

FIG. 6 is a perspective view that illustrates a phase change memory device including conductive sidewall spacers that do not extend along an entirety of the bit line and a threshold voltage reduction liner, in accordance with one embodiment of the present disclosure.

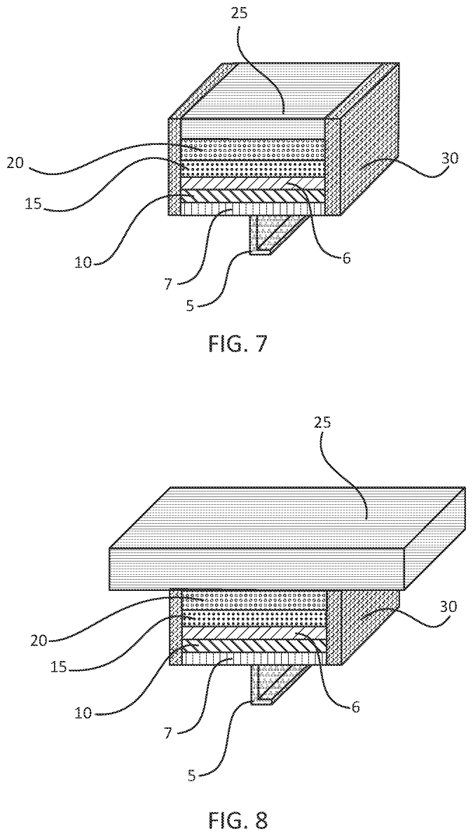

FIGS. 7 and 8 depict yet further embodiments of the present disclosure. In the embodiments depicted in FIGS. 7 and 8, the stack 50 also includes a resistive projection liner 6 and a threshold voltage reducing liner 7 in addition to the phase change material layer 10, the first electrode 5, the dielectric layer 15 and the second electrode 20. The resistive projection liner 6 is a layer that is present between the first electrode 5 and the phase change material layer 10. The threshold reducing liner 7 is a layer that is present between the phase change material layer 10 and the dielectric layer 15.

FIG. 7 is a perspective view that illustrates a phase change memory device including conductive sidewall spacers that extend along an entirety of the bit line, a resistive projection liner and a threshold voltage reduction liner, in accordance with one embodiment of the present disclosure.

FIG. 8 is a perspective view that illustrates a phase change memory device including conductive sidewall spacers that do not extend along an entirety of the bit line, a resistive projection liner and a threshold voltage reduction liner, in accordance with one embodiment of the present disclosure.

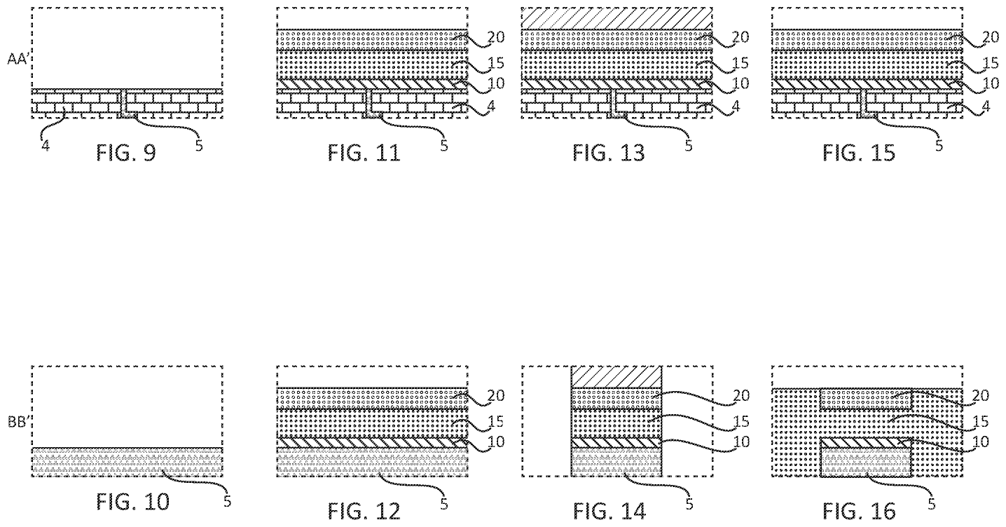

The structures depicted in FIGS. 1-8 are now described in greater detail with reference to the method depicted in FIGS. 9-34.

In another aspect, a method of forming a phase change memory device is provided. In one embodiment, the method may include forming a material stack 50 on a first electrode 5. The material stack 50 includes a phase change material layer 10 that is present on the first electrode 5, a dielectric layer 15 that is present on the phase change material layer 10, and a second electrode layer 20 that is present on the phase change material layer 10. The material stack may be etched along a first direction to form a first cell. A bit line 25 is formed atop the second electrode layer 20. The bit line 25 and the stack 50 are then etched along a section direction. A conducting material is then deposited conformally to provide a conformal liner 29 around two sidewalls of a cell provided by the etched stack. The conformal liner 29 of the conducting material may then be etched back to provide two conductive sidewall spacers 30 in electrical communication between the second electrode 20 and the sidewall of two sides of the phase change material layer 10.

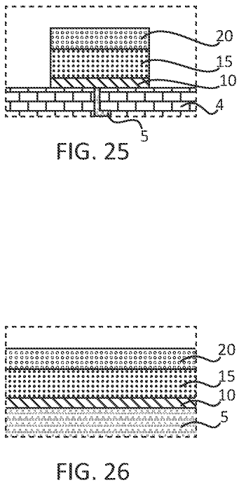

FIGS. 9-24 illustrate one embodiment of a method for forming the structure depicted in FIG. 1, as well as FIGS. 3, 5 and 7. FIGS. 9, 11, 13, 15, 17, 19, 21, and 23 are cross-sections along section line AA in FIG. 1. FIGS. 10, 12, 14, 16, 18, 20, 22 and 24 are cross-sections along section line BB in FIG. 2. FIGS. 25-34 illustrate one embodiment of a method for forming the structure depicted in FIG. 2, as well as FIGS. 4, 6 and 8. FIGS. 25, 27, 29, 31 and 33 are cross-sections along section line AA in FIG. 2. FIGS. 26, 28, 30, 32 and 34 are cross-sections along section line BB in FIG. 2

FIGS. 9 and 10 illustrates one embodiment of an initial structure used in the method, in which the first electrode 5 and the dielectric material 4, in which the first electrode is present is formed. The conductive metallic material of the first electrode 5 may be formed by a deposition process such as, for example, CVD, PECVD, physical vapor deposition (PVD), sputtering, atomic layer deposition (ALD) or plating. A planarization process or an etch back process may follow the deposition of the conductive metallic material that provides the bottom electrode 5. As is shown, the bottom electrode 5 has a topmost surface that is coplanar with a topmost surface of the dielectric material 4. The exemplary structure shown in FIG. 9 may also be formed by first providing the first electrode 5 on a surface of a base substrate (not shown) by deposition of a conductive metallic material, followed by patterning the deposited conductive metallic material by lithography and etching. The insulating material 5 may then be formed by deposition of a dielectric material, followed by planarization or an etch back process. The insulating material 4 can be formed utilizing a deposition process including, for example, chemical vapor deposition (CVD), plasma enhanced chemical vapor deposition (PECVD), spin-on coating, evaporation or chemical solution deposition. The base substrate may include a semiconductor material, an insulator material, and/or conductive material.

FIGS. 11 and 12 depicts one embodiment of forming the phase change material layer 10, dielectric layer 15 and top electrode 20.

The phase change material layer 10 may be deposited. In some embodiments, the phase change material layer 10 is deposited using a physical vapor deposition process. In one example, the physical vapor deposition process may be sputtering. As used herein, “sputtering” means a method of depositing a film of material on a semiconductor surface. A target of the desired material, i.e., source, is bombarded with particles, e.g., ions, which knock atoms from the target, and the dislodged target material deposits on the deposition surface. Examples of sputtering techniques suitable for depositing the phase change material layer 10 include, but are not limited to, DC diode sputtering (“also referred to as DC sputtering”), radio frequency (RF) sputtering, magnetron sputtering, and ionized metal plasma (IMP) sputtering.

Other deposition processes may also be employed for forming the phase change material layer 10, which can include atomic layer deposition and chemical vapor deposition. Atomic layer deposition can form monolayers of material. Atomic layer deposition can be employed to provide an ultra-thin layer, e.g., a layer having a thickness less than 15 nm.

In some embodiments, a resistive projection liner 6 may be formed between the layer including the first electrode 5 and the phase change material layer 10. This step can be used for a process flow that can provide the structures depicted in FIGS. 3 and 4, as well as FIGS. 7 and 8. The deposition process steps described for the phase change material layer 10 may be similarly applied for the resistive projection liner 6 with adjustments to accommodate the different chemical compositions for the separate layers.

The dielectric layer 15 may then be deposited atop the phase change material layer 10. The dielectric layer 15 may be deposited using chemical vapor deposition.

In some embodiments, a threshold voltage (Vth) reducing liner 7 may be formed between the phase change material layer 10 and the dielectric layer 15. This step can be used for a process flow that can provide the structures depicted in FIGS. 5 and 6, as well as FIGS. 7 and 8. The deposition process steps described for the phase change material layer 10 may be similarly applied for the threshold voltage (Vth) reducing liner 7 with adjustments to accommodate the different chemical compositions for the separate layers.

FIGS. 11 and 12 further depicts forming a second electrode 20 on the upper surface of the phase change material layer 10. The second electrode 46 (also referred to as top electrode) may comprise one of the conductive metallic materials mentioned above in providing the first electrode 5. In some embodiments, the second electrode 10 and the first electrode 5 comprise a same conductive metallic material. In other embodiments, the second electrode 10 and the first electrode 5 comprise a different conductive metallic material. The second electrode 10 may be formed using plating, electroplating, sputtering or other deposition methods including forms of physical vapor deposition, and chemical vapor deposition, etc.

FIGS. 13 and 14 illustrate one embodiment of etching the stack to confine the structure along the BB cross section, as illustrated in FIG. 14. The etch process may be an anisotropic etch, such as reactive ion etching. An etch mask, e.g., photoresist mask 21, may be formed using photolithography to pattern the stack for etching.

FIGS. 15 and 16 illustrate one embodiment of filling the openings formed by the etch step described in FIGS. 13 and 14 with a dielectric material 8. For example, an oxide, such as silicon oxide, may be deposited using a deposition process, such as chemical vapor deposition (CVD). Following deposition, a planarization process, such as chemical mechanical planarization (CMP) may be employed to planarize the structure.

FIGS. 17 and 18 illustrate one embodiment of forming a bit line 25. The bit line 25 may be formed using a deposition process to deposit the bit line metal. The deposition process may be plating, electroplating, electroless plating, physical vapor deposition, chemical vapor deposition and/or atomic layer deposition.

FIGS. 19 and 20 illustrate one embodiment of etching the bit line metal. In some embodiments, the bit line metal is etched to confine the structure in the AA cross section. The bit line metal may be etched using an anisotropic etch, such as reactive ion etching. An etch mask, e.g., photoresist mask 23, may be formed using photolithography to pattern the bit line metal for etching.

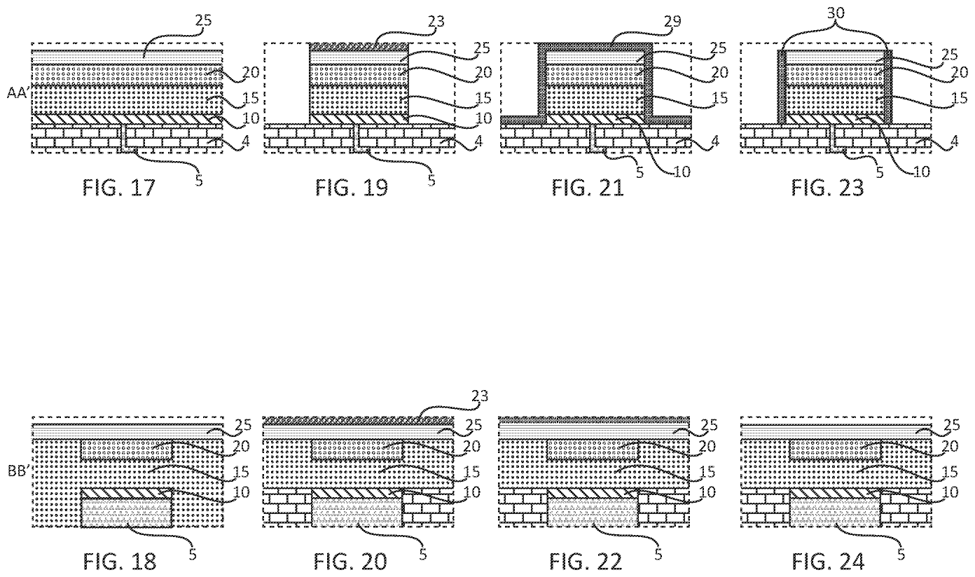

FIGS. 21-24 illustrate one embodiment of forming the conductive sidewall spacer 30, as illustrated in FIG. 1. In some embodiments, a conformal liner 29 of material for the conductive sidewall spacer 30 is first formed as depicted in FIGS. 21-22. By “conformal” it is meant that the deposited layer has substantially same thickness along its entirety, e.g., in both vertically orientated and horizontally orientated portions of the liner/layer. The conformal liner 29 may be deposited using plating, electroplating, electroless plating, chemical vapor deposition and/or atomic layer deposition. The conformal liner 29 may then be etched using an etch back process to remove the horizontally orientated portions, while leaving the vertically orientated portions to remain and provide the conductive sidewall spacer, as depicted in FIGS. 23-24. The etch back process may be an anisotropic etch, such as reactive ion etching. This conductive spacer 30 is depicted in FIGS. 1, 3, 5 and 7. The process flow illustrated in FIGS. 9-24 may provide a spacer 30 along an entirety of the bit line 25.

The process flow illustrated in FIGS. 25-34 illustrate one embodiment for forming a conductive sidewall spacer 30 that does not extend along an entirety of the bit line 25, as depicted in the structures described above with reference to FIGS. 2, 4, 6 and 8.

In some embodiments, beginning with an initial structure that has been described above with reference to FIGS. 9-12, an etch process is applied to etch the stack, e.g., etch the phase change material layer 10, the dielectric layer 15 and the top electrode 20 to confine the structure in the AA cross-section, as depicted in FIGS. 25 and 26. The etch process may include photolithography and anisotropic etching, such as reactive ion etching (RIE).

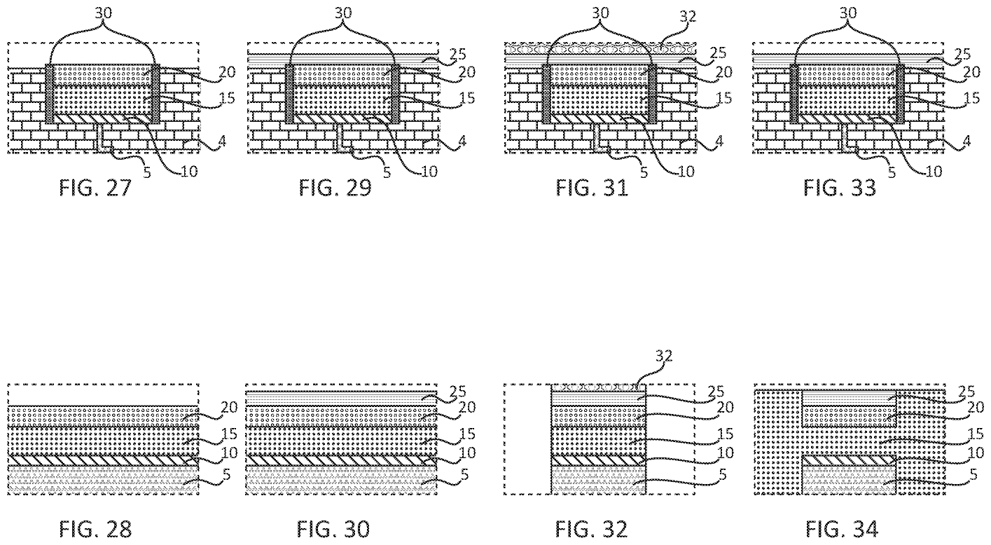

FIGS. 27-28 illustrate forming the conductive sidewall spacer 30. The conductive sidewall spacer 30 may be forming using a conformal liner deposition for the material of the conductive sidewall spacer 30 followed by an etch back process. These process steps have been described above with reference to FIGS. 21-24. Following forming the conductive sidewall spacer 30, a deposition process is employed to deposit a dielectric 31, such as an oxide, e.g., silicon oxide, or nitride, e.g., silicon nitride. A planarization process, such as chemical mechanical planarization (CMP) may be performed thereafter providing the structure illustrated in FIGS. 27-28.

FIGS. 29-30 illustrate depositing the bit line metal for the bit line 25. The bit line metal depicted in FIGS. 29-30 is similar to the bit line metal that is illustrated in FIGS. 17 and 18.

FIGS. 31-32 illustrate applying an etch process to etch the bit line metal an provide a geometry for the bit line 25 that is confined in the BB cross-sectional as illustrated in FIG. 32. The etch process may employ photolithography (to produce a photoresist mask 32) and anisotropic etching, such as reactive ion etching.

FIGS. 33-34 illustrate one embodiment of removing the etch mask 32 and depositing a fill dielectric 33. The fill dielectric 33 may be an oxide, such as silicon oxide, or a nitride, such as silicon nitride.

The process flow illustrated in FIGS. 25-34 illustrate one embodiment for forming a conductive sidewall spacer 30 that does not extend along an entirety of the bit line 25, as depicted in the structures described above with reference to FIGS. 2, 4, 6 and 8.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Having described preferred embodiments of a system and method for providing a phase change memory device with partial sidewall spacer contact (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A phase change memory device comprising:
a stacked structure of a first electrode with a first cross-sectional area, a phase change material layer that is present on the first electrode, a dielectric material layer that is present on the phase change material layer, and a second electrode with a second cross-sectional area that is present on the dielectric layer, wherein a second cross sectional area is greater than the first cross-sectional area; and
a conductive sidewall spacer that is present on two sidewalls of the stacked structure providing electrical communication between the second electrode and the phase change material layer.

2. The phase change memory device of claim 1, wherein the first electrode is electrically separated from the conductive sidewall spacer.

3. The phase change memory device of claim 1, wherein the conductive sidewall spacer is comprised of a conductive material selected from the group consisting of titanium (Ti), titanium nitride (TiN), tantalum (Ta), tantalum nitride (TaN), tungsten and combinations thereof.

4. The phase change memory device of claim 1, wherein the conductive sidewall spacer is in direct contact with two sidewalls of the phase change material layer.

5. The phase change memory device of claim 1, wherein thickness of the phase change material layer is 15 nm or less.

6. The phase change memory device of claim 1 further comprising a bit line on the second electrode, wherein the conductive sidewall spacer extends along an entirety of the bit line.

7. The phase change memory device of claim 1 further comprising a bit line on the second electrode, wherein the conductive sidewall spacer does not extend along an entirety of the bit line.

8. A phase change memory device comprising:
a stacked structure of a first electrode with a first cross-sectional area, a projection liner layer on the first electrode, a phase change material layer that is present on the projection liner layer, a dielectric material layer that is present on the phase change material layer and a second electrode with a second cross-sectional area that is present on the dielectric layer, wherein a second cross sectional area is greater than the first cross-sectional area; and
a conductive sidewall spacer that is present on two sidewalls of the stacked structure providing electrical communication between the second electrode and the phase change material layer.

9. The phase change memory device of claim 8, wherein the first electrode is electrically separated from the conductive sidewall spacer.

10. The phase change memory device of claim 8, wherein the conductive sidewall spacer is comprised of a conductive material selected from the group consisting of titanium (Ti), titanium nitride (TiN), tantalum (Ta), tantalum nitride (TaN), tungsten and combinations thereof.

11. The phase change memory device of claim 8, wherein the conductive sidewall spacer is in direct contact with two sidewalls of the phase change material layer.

12. The phase change memory device of claim 8, wherein thickness of the phase change material layer is 15 nm or less.

13. The phase change memory device of claim 8 further comprising a bit line on the second electrode, wherein the conductive sidewall spacer extends along an entirety of the bit line.

14. The phase change memory device of claim 8 further comprising a bit line on the second electrode, wherein the conductive sidewall spacer does not extend along an entirety of the bit line.

15. A phase change memory device comprising:
a stacked structure of a first electrode with a first cross-sectional area, a phase change material layer that is present on the first electrode, a threshold voltage reduction layer that is present on the phase change material layer, a dielectric material layer that is present on the threshold voltage reduction layer and a second electrode with a second cross-sectional area that is present on the dielectric layer, wherein a second cross sectional area is greater than the first cross-sectional area; and
a conductive sidewall spacer that is present on two sidewalls of the stacked structure providing electrical communication between the second electrode and the phase change material layer.

16. The phase change memory device of claim 15, wherein the first electrode is electrically separated from the conductive sidewall spacer.

17. The phase change memory device of claim 15 further comprising a projection liner layer between the first electrode and the phase change material layer.

18. The phase change memory device of claim 15, wherein thickness of the phase change material layer is 15 nm or less.

19. The phase change memory device of claim 15 further comprising a bit line on the second electrode, wherein the conductive sidewall spacer extends along an entirety of the bit line.

20. The phase change memory device of claim 15 further comprising a bit line on the second electrode, wherein the conductive sidewall spacer does not extend along an entirety of the bit line.
